(19) United States
(12) Patent Application Publication
(10) Pub. No.: US 2015/0160305 A1
(43) Pub. Date: Jun. 11, 2015

(54) METHOD OF TESTING A DIMMING LIGHTING SYSTEM

(71) Applicant: General Electric Company, Schenectady, NY (US)

(72) Inventors: Laszlo Sandor ILYES, Lyndhurst, OH (US); Magda Theresa VALERIAN, Willoughby Hills, OH (US)

(73) Assignee: General Electric Company, Schenectady, NY (US)

(21) Appl. No.: 14/102,534

(22) Filed: Dec. 11, 2013

(51) Int. Cl. G01R 31/44

(52) U.S. Cl. CPC G01R 31/44

(57) ABSTRACT

A diagnostic device for testing a lighting fixture apparatus is provided. The lighting fixture includes at least one ballast configured to receive a dimming test signal. The diagnostic device includes a controller module configured to trigger a test sequence when the ballast receives the dimming test signal. An output current of the ballast is adjusted in accordance with predetermined values of the dimming test signal, the adjusted output current setting a dimming level of the lighting fixture.

### FIELD OF THE INVENTION

The present invention relates generally to diagnostic devices for verifying operability of a dimming feature of a lighting fixture (also, commonly referred to as “a luminaire” or “a lighting fitting”) during installation of the lighting fixture.

### BACKGROUND OF THE INVENTION

The purpose of a lighting-control system is to eliminate energy waste while providing a productive visual environment. Lighting control means having the ability to illuminate where and when it's needed and the power to conserve when illumination is not needed. To accomplish this, controls can provide the right amount of light where it's needed and when it's needed—either automatically or at a user's discretion. Lighting controls, such as automatic shut-off or a dimming feature, can reduce lighting energy consumption and produce energy savings. Dimming a light fixture saves energy when operating a light source and also allows a user to adjust the intensity of the light source to a desired level. Many indoor and outdoor facilities, such as homes, buildings, parking lots, and streets, include light source dimming circuits.

The most common use of dimming is for indoor applications, such as for dimming a room. Dimming is also ideally suited to energy management applications such as daylight harvesting. For example, in outdoor applications, photoelectronic controllers (referred herein as a “photocontrollers” or “photocontrol”) are commonly used to automatically switch on luminaire fixtures on at dusk and off at dawn. Luminaire fixtures may be wired to include a photocell which responds to ambient light and automatically turns the lamp on and off at sunset and sunrise. These luminaires fixtures are typically used to light roadways, parking lots and other large outdoor areas. These devices sense the intensity of the ambient light and switch the luminaires on and off accordingly. Street lighting luminaires are typically provided with an electrical receptacle for receiving a photoelectric controller on the luminaire housing. With street lighting luminaires, as daylight levels increase, a photo sensor signals dimmable ballasts to reduce the lighting system's light output and power input, saving energy. As night approaches, the lights increase in intensity.

In applications with daylight harvesting, photocontrol dimming can provide a smooth and unnoticeable transition to lower electric light levels as daylight levels increase, all while maintaining the desired light level to produce significant lighting energy savings. For example, a controller turns a lighting fixture on at dusk, dims at the predetermined time to a preset amount, returns to full brightness at 5 a.m., and turns off at dawn, offering 20-30 percent energy savings above normal photocell operation.

However, light control problems can occur during dimming. Often, these problems can be traced backed to faulty wiring, mismatched components, and other design and installations issues. For these reasons, it is recommended that the user verify the operation of the dimming equipment and all other lighting controls after installation.

Historically, individuals installing controllers on street lights during the daytime have found it easy to test on/off operation of the fixture. This is accomplished by using one's hand to cover the photocell in order to simulate a nighttime condition to the controller. If the controller and the associated street light are in proper working order, the street light will illuminate a short time interval after the photocell is placed in this dark condition. And then by removing one's hand from in front of the photocell, allowing daylight to again illuminate the photocell, the fixture will be seen to turn off after a short time interval.

However, the cues to the controller needed to initiate dimming are not so easily simulated by the installer. For example, dimming of the street light may only be initiated by the controller after several predetermined hours have elapsed after sunset. Or the controller may be programmed to dim at a specific time at night, and this specific time may be many hours before or after the lighting controller has been installed on the fixture. Indeed, the clock implemented inside the controller may require many hours in order to accurately synchronize to the correct time.

In the case of a wireless controller that has just been installed on a street light, the controller may not immediately connect to the wireless network, and therefore not be manually dimmable for a significant amount of time after the installation. For all of these reasons, and others, it is generally not reasonable or convenient for an installer to wait the amount of time needed in order to establish whether or not the fixture dims properly after installation.

The above-described shortcomings significantly limit the ability to verify the dimming operation of a lighting fixture immediately after installation of the lighting fixture. Therefore, there remains a need for a device and method wherein the user can install the light fixture and controller and test immediately once the equipment has been powered. The user can immediately test the equipment as installed and intact before it would be otherwise practical to do in normal operation. There also remains a need to verify that all components within the light fixture are functional such that troubleshooting is simplified.

There remains a further need to provide a dimming verification technique that may be integrated with a light fixture, so as avoid the use of external equipment, such as a separate photocontroller to test functionality. There remains a need for an integral self-test function, where the testing is programmed and carried out independently by the circuitry. In the event of a malfunction in the test, a warning light an alarm, or a combination thereof alert the user of the test malfunction.

There remains a further need for an automatic self-testing circuit which automatically performs a time-based test and diagnostic routine upon installation of the light fixture and indicates failures by a status indicator. There also remains a need for a selective user-initiated mode, when if the light fixture fails to dim after an extended time period during the automatic self-testing mode. The user can initiate a predetermined lighting pattern to the photocell to start a temporary dimming mode.

### SUMMARY OF EMBODIMENTS OF INVENTION

In certain circumstances, embodiments of the present invention provide a diagnostic device for testing a lighting fixture apparatus. The lighting fixture includes at least one ballast configured to receive a dimming test signal. The diagnostic device includes a controller module configured to trigger a test sequence when the ballast receives the dimming test signal. An output current of the ballast is adjusted in accordance with predetermined values of the dimming test signal, the adjusted output current setting a dimming level of the lighting fixture.

In other embodiments, a method is provided for testing a lighting fixture, which includes providing at least one light source and at least one ballast or driver in a lighting fixture; providing a controller module attached to the lighting fixture and coupled with the ballast or driver; providing a microcontroller within the controller module; and providing at least one dimming test signal and at least one dimming control value from the microcontroller to cause the ballast or driver to provide dimmable output from the light source and instruct the microcontroller to enter a dimming testing mode automatically when power is supplied to the lighting fixture.

Further features and advantages of the invention, as well as the structure and operation of various embodiments of the invention, are described in detail below with reference to the accompanying drawings. It is noted that the invention is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS

FIG. 1 illustrates a partial side view of an exemplary dimmable outdoor lighting fixture with a control module in accordance with the present disclosure;

FIG. 2 is a block diagram of the primary components of the controller module illustrated in FIG. 1 in accordance with the present disclosure;

FIG. 3 is a schematic diagram representation of an exemplary ballast or LED driver in accordance with the present disclosure;

FIG. 4 is a graphical illustration of exemplary current output in which a first embodiment of the present disclosure can be practiced;

FIG. 5 illustrates an outdoor lighting fixture with a photo eye coupled to the lighting fixture in which a second embodiment of the present disclosure can be practiced;

FIG. 6 is a flowchart of an exemplary method of practicing a first embodiment of the present disclosure; and

FIG. 7 is a flowchart of an exemplary method of practicing a second embodiment of the present disclosure.

The present disclosure may take form in various components and arrangements of components, and in various process operations and arrangements of process operations. The present disclosure is illustrated in the accompanying drawings, throughout which, like reference numerals may indicate corresponding or similar parts in the various figures. The drawings are only for purposes of illustrating preferred embodiments and are not to be construed as limiting the disclosure. Given the following enabling description of the drawings, the novel aspects of the present disclosure should become evident to a person of ordinary skill in the art.

### DETAILED DESCRIPTION OF VARIOUS EMBODIMENTS

The following detailed description is merely exemplary in nature and is not intended to limit the applications and uses disclosed herein. Further, there is no intention to be bound by any theory presented in the preceding background or summary or the following detailed description. While embodiments of the present technology are described herein primarily in connection with lighting fixture having an electronic control ballast, the concepts are also applicable to other types of lighting fixtures with any electrical or electronic dimming control which adjusts the brightness of illumination of a lump such as incandescent lighting or high intensity/high intensity gas filled lamp.

While the present control is described in terms of fluorescent lamp having an internal electronic control ballast, the present invention may

In at least one aspect, the present disclosure provides a diagnostic device and method for verifying operability of a dimming feature of a lighting fixture (also, commonly referred to as “a luminaire” or “a lighting fitting”) during installation of the lighting fixture. In at least one aspect, the device and method involve an automatic operation where a photocontroller automatically outputs a test dimming signal for a predefined time when an AC power source is applied to the lighting fixture.

The dimming signal is only provided for a brief amount of time so that the user can verify the dimming operation. Once the time limit has been reached, the photocontroller will return to normal operation. The test dimming signal may not be activated again unless a predefined event occurs to initiate the test sequence.

In another aspect, the present disclosure provides a device and method that initiates a startup dimming sequence from one or multiple predefined dimming levels. The end user can verify operation of dimming circuit when this sequence is initiated. The user may selectively initiate the dimming verification based on a photocell of the photocontroller receiving a predefined pattern of signals.

Various embodiments of the device and method enable the user to test a light fixture immediately after installation of the light fixture once the equipment has been powered. The user can immediately test the equipment as installed and intact. Various embodiments enable the user to verify that all components within the light fixture are functional such that troubleshooting is simplified.

Various embodiments provide a dimming verification technique that may be integrated with a light fixture, so as avoid the use of external equipment, such as a separate photocontroller to test functionality. Various embodiments provide an integral self-test function, where the testing is programmed and carried out independently by the circuitry. In the event of a malfunction in the test, a warning light, an alarm or a combination thereof to advise of the test malfunction.

In various embodiments, an automatic self-testing circuit is provided which automatically performs a time-based test and diagnostic routine upon installation of the light fixture and indicates failures by a status indicator. Various embodiments provide a selective user-initiated mode, when the light fixture fails to dim during the automatic self-testing dimming mode after an extended time period. The user can initiate a predetermined lighting pattern to the photocell to start a temporary dimming mode.

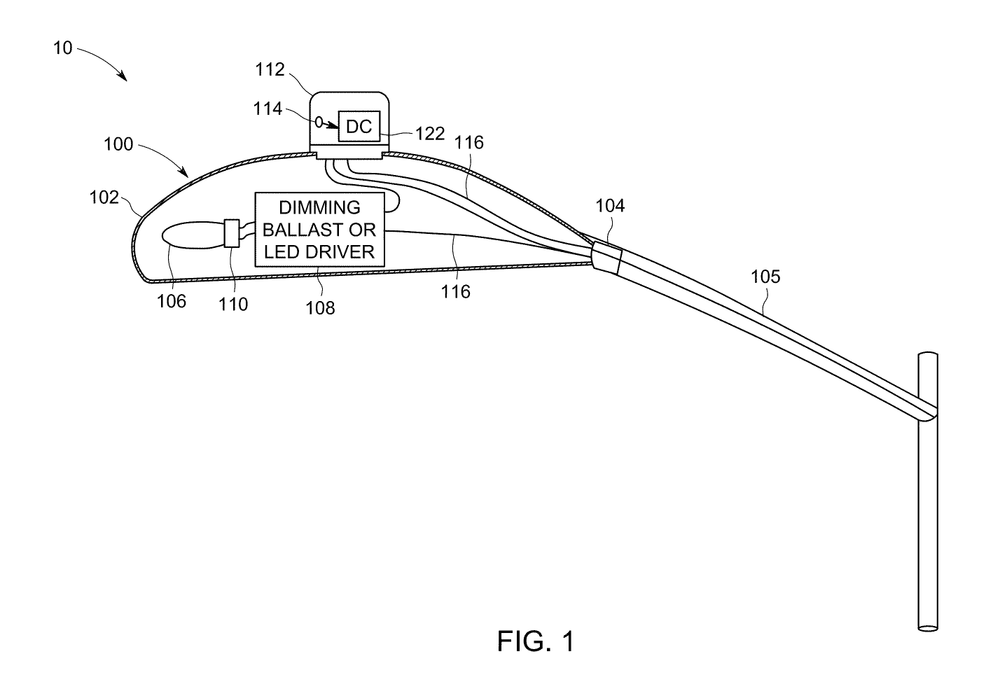

An exemplary embodiment of an energy-saving lighting control system 10, which controls the level of light provided to a lighting fixture, such as standard street light type luminaire 100 is illustrated in FIG. 1. The system 10 can be used to verify the operability of the dimming feature of the light fixture immediately upon installation of the light fixture. The system includes a housing and a mounting system. Electronics for the lighting fixture are installed inside the mounting system. In various embodiments, the electronics are entirely enclosed within the mounting system as a single unit. In other embodiments, however, the electronics may be distributed, having some components outside the mounting system and having some components within the fixture housing.

FIG.1 illustrates details of an exemplary outdoor lighting fixture apparatus including the luminaire fixture assembly 100 with a fixture housing structure 102 having an inlet conduit 104 for receiving power wiring. In FIG. 1, the fixture housing may be mounted to a building or to a pole or other support structure 105 for a particular outdoor lighting application. One or more light sources 106, such as fluorescent lamps, LEDs, incandescent lamps or arrays thereof, are supported in the fixture housing 102 via sockets 110. The light source(s) 106 is driven by a ballast or driver 108, also supported in the housing 102.

As shown in FIG. 1, in various embodiments, a controller module 112 may be mounted to the top of the fixture housing. The controller module 112 may comprise a photocontroller 114, which includes a sensor (such as a photocell or photo sensor) operative to sense ambient light near the fixture assembly for controlling turn on and turn off timing in certain embodiments. Electrical connections via wires 116 are routed into housing 102.

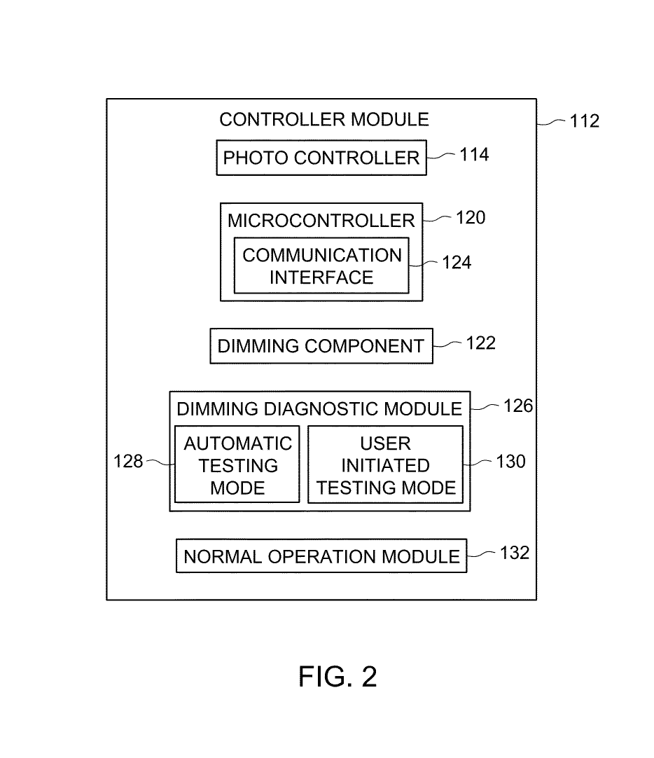

The power line is selectively switched by the controller module 112 and provided to the ballast or driver 108, such that the ballast or driver 108 is selectively powered or unpowered by the operation of the controller module 112. The controller module 112 may be operative according to a switch control signal from a microcontroller 120 (FIG. 2) of the controller module 112.

As shown in FIG. 2, the controller module 112 can include a dimming component (e.g., dimming command component) 122, which can be any suitable circuitry, hardware, processor-executed software or firmware, logic, etc., which operates to selectively provide one or more dimming control values or signals to the ballast or driver 108 so as to cause the ballast or driver 108 to provide dimmable output from the light source(s) 106. The dimming component 122 is operatively coupled to the microcontroller 120.

The microcontroller 112 also includes a communications interface 124 providing communications interfacing which may include on-site communications or off-site remote communications. For example, the on-site communications may include visual indicators, audible indications or a combination thereof. Moreover, the controller module 112 may also include current and/or voltage measurement or sensing circuitry or components for sensing input or switched power conditions for dimming control.

The controller module 112 in certain embodiments also includes a photocontroller 114 comprising a sensor, such as a photo sensor or a photocell, which senses ambient light proximate the fixture assembly 100 and provides a sensed light signal or value to the dimming component 122. The dimming component 122 selectively provides the dimming control value or values (e.g., 0-10V signal, messages, etc.) to the ballast or driver 108 in certain embodiments based at least in part on the sensed light signal or value.

For example, the dimming component 122 may be programmed or otherwise configured to provide dimmed light via the dimming control value selection at dawn and/or dusk for reduced power consumption and for esthetic lighting, rather than the normal full on/full off operation. In certain embodiments, moreover, the dimming component 122 may be operative to selectively dim the light output during certain times for energy conservation, for instance, to dim unused roadways to a safe but efficient level in the middle of the night, with possible dimming control modification/override according to signals or values received from an occupancy/motion sensor operatively coupled with the microcontroller 120. In certain embodiments, moreover, the dimming control component 122 may be implemented as one or more software components executed by the microcontroller 120.

In various embodiments, during normal dimming operations 132, the dimming component 122 is operative to selectively provide the dimming control value based at least in part on a received RF signal or value from an external RF device. For instance, an RF command signal can be sent to the controller module 112 wirelessly for initiating dimmed, full on, full off, flashing operation, or combinations thereof by a control device having an RF transmitter.

The dimming component 122 may thus provide the dimming control value(s) to control the light output according to one or more criteria, some of which may be externally actuated (e.g., via a photo eye (PE) sensor), a motion sensor, and/or RF device or combinations thereof) and some of which may be preprogrammed in the controller module 112.

In FIG. 1, luminaire 100 comprises a lamp controller 112, which is microcontroller-based and adapted to receive power from an AC power source. In FIG. 2, the controller module 112 is further shown to include a dimming diagnostic module 126 and a normal operation module 132. The dimming diagnostic module 126 operates to verify the operation of the dimming feature of the light fixture immediately after the installation of the light fixture.

In various embodiments, the dimming diagnostic module 126 also operates to enable the user to immediately test the equipment of the lighting system as installed and intact. This feature enables the user to verify that all components within the light fixture are functional such that troubleshooting is simplified. The test dimming signal is only provided for a brief time period after power up so that the user can verify the dimming operation at installation. Once a predetermined time limit has been reached, the photocontroller 114 will return the light fixture to a normal operating mode 132. The test dimming signal may not be activated again unless a predefined event occurs to initiate the test sequence.

To activate the dimming sequence, the user need only to cycle the AC power or supply a predefined light sequence. Thus, the dimming diagnostic module 126 can include two modes of operation: an automatic dimming self-testing mode 128, which is initiated when the AC power is supplied, and a user-initiated dimming test mode 130, which is initiated based on a predefined light sequence.

The automatic dimming self-testing mode 128 automatically verifies the operation of the dimming feature of the luminaire by initiating a dimming test sequence after the installation of the luminaire and once the AC power is applied. In the automatic mode 128, the photocontroller 114 outputs a predefined dimming level or levels to the user to indicate whether the fixture is operating properly. This is a convenient way to trigger the dimming test, since the controller will typically be powered continuously in normal use.

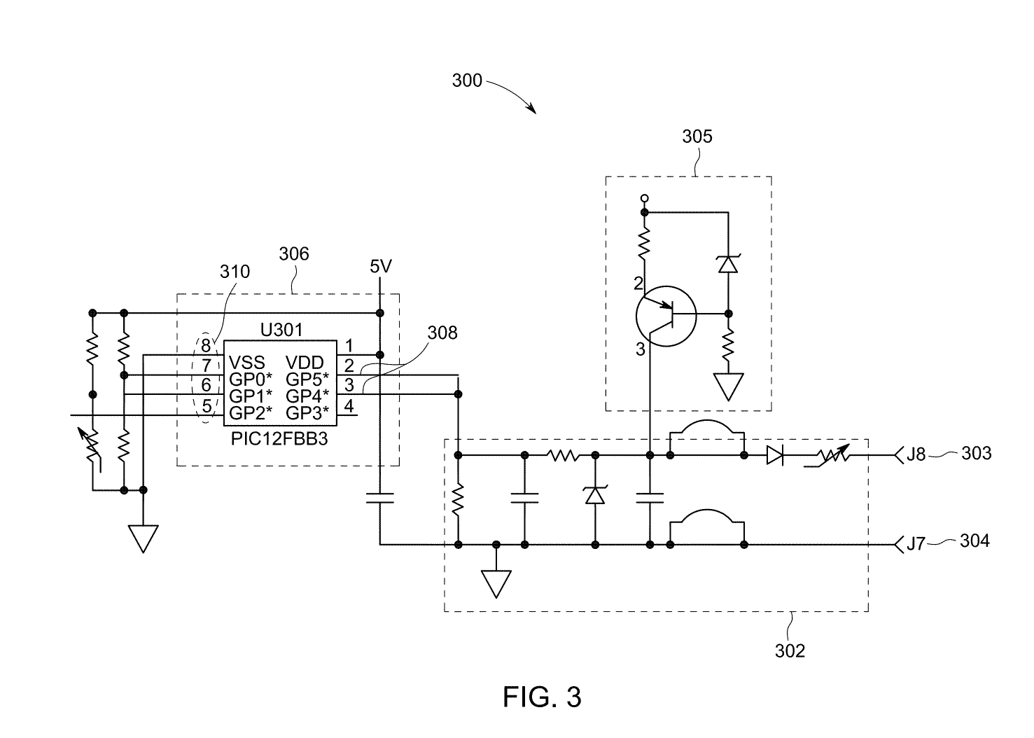

FIG. 3 is a schematic diagram representation of an exemplary ballast or LED driver 300 in which a first embodiment of the present invention may be practiced. The ballast 300 regulates the amount of electrical power applied to a light source 106m which may an individual LED, or an LED array (not shown). In the ballast 300, a standard 0-10V dimming lead, or digital addressable lighting interface (DALI) lead, is used to inject a dimming test sequence and program the output current level of the ballast. The output current of the ballast is ultimately supplied to the light source 306 (an LED or LED array), to control dimming at the predefined dimming levels as defined by the dimming test sequence.

More specifically, the exemplary ballast 300 includes an input and line conditioning segment 302, including standard existing 0-10V and/or DALI input terminals 303 and 304. Also included is a constant current source segment 305, along with a microcontroller segment 306. In the ballast 300, a test dimming signal, discussed more fully below, is provided at the input terminals 303 and 304 to notify the microcontroller 306 that the output current of the ballast is about to be programmed. The input power supplied to the controller is supplied by a conventional AC power source. The microcontroller 306 provides all the timing and control functions of the controller electronics.

The controller 112 may contain pre-programmed dimming test signals, which are stored in the memory of the controller. At a factory, or during installation of a lighting system, the dimming test signals are provided as inputs via the input terminals 303 and 304. A user employing a handheld device or some other interface can connect the device to the input terminals 303 and 304 and provide the dimming test signals as input for output current of the ballast.

The light controller contains an automatic dimming self-testing mode 128 for the user to check whether the dimming feature is operating properly. When the automatic dimming self-testing mode 128 is active, the user can verify the operability of the dimming feature and the lamp components using a visual and/or audible indicator. In this case, the test dimming sequence is self-powered. When the AC power switches on, the dimming feature of the lamp will automatically turn on.

In an example of the automatic dimming self-testing mode, the dimming test signal, being treated as a passive input to the input and line conditioning segment 302, will be received at input pins 308 of the microcontroller 306. The microcontroller 306 will read and interpret the test dimming signals as an instruction to enter an output current dimming test mode, via an output port 310. After conclusion of the automatic dimming self-testing mode cycle, the microcontroller 306 will return the light fixture to the normal operation module 132.

After entering the automatic dimming self-testing mode, the microcontroller 306 will read the dimming test signal. The dimming test signal is a voltage signal that instructs the microcontroller 306 at what level to specifically set the output current.

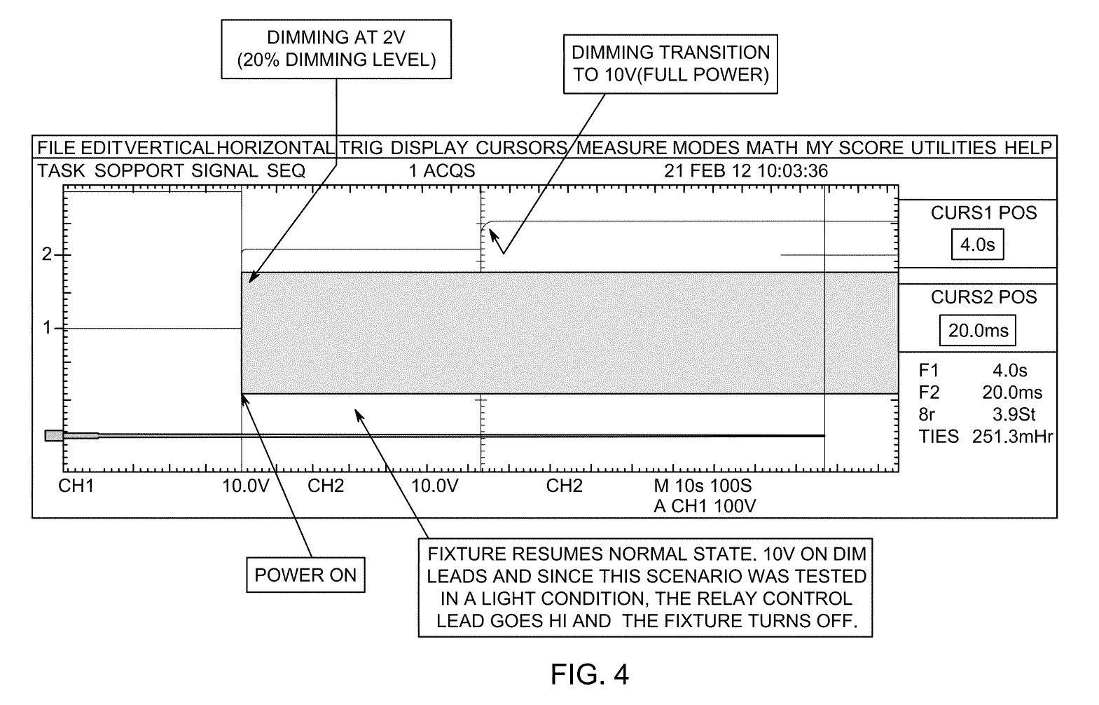

FIG. 4 represents an example of the dimming levels during the automatic dimming self-testing mode 128. Power is supplied to the lighting fixture to automatically test the dimming feature. A photocontroller is placed in a testing dimming sequence once the AC power is applied to the photocontroller. In this application, the photocontroller outputs a predefined dimming level or levels so that the user can determine whether the fixture is operating as intended.

The dimming ballast output of the controller is determined by test dimming signals, which in turn determines the output voltage of the light source 106. For example, the start-up dimming sequence may be preprogrammed in software of the microcontroller 120 to immediately dim the lighting fixture to 20% dimming level (2 volts provided on a 0-10 volt dimming leads) for approximately 4 seconds.

In FIG. 4, once the power is supplied, the controller immediately dims the light to 2 volts, which indicates a 20% dimming level for approximately 4 seconds. Then, the lighting fixture undergoes a dimming transition. The controller increases the light to 10 volts, which indicates a 100% (10 volts provided on 100 volts) normal full on operation for 3 seconds such that the light begins to operate in normal operating mode 132.

During the diagnostic testing, the microprocessor compares the dimming level with the predefined level(s) to determine whether the dimming feature is working properly. This example was tested in a daylight condition; therefore, the relay control lead goes High after completion of the diagnostic test and the lighting fixture turns off.

If a lighting fixture under test does not dim according to the predefined dimming level or level(s), this may indicate a defective lighting fixture. An audible and/or visual status indicator such as, for example, an LED or a buzzer, may be provided to alert the user of the malfunctioning lighting fixture. In the event of a test failure, the lighting fixture can be manually tested by the user according to a second embodiment of the present invention.

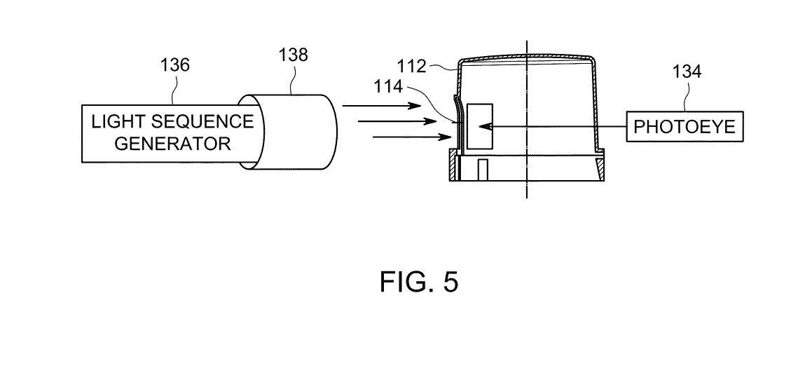

FIG. 5 illustrates an outdoor lighting fixture with a photo eye 134 for coupling to the lighting fixture in which a second embodiment of the present invention may be practiced. For example, the lighting fixture may be configured to include a photo eye 134 set within the controller mounting structure 112. The photo eye 134 may include, for example, motion sensors, light sensors, or cameras to control various activities. The photo eye 134 may also house the control electronics (e.g. processing circuit, logic modules, memory, etc.) associated with such a sensor or camera.

In the user-initiated testing dimming mode 130 of the second embodiment, the user can initiate the verification operation of the dimming circuit by initiating a startup dimming sequence. If the lighting fixture fails to dim after an extended time period during the automatic self-testing mode in the first embodiment, the user can initiate a predetermined lighting pattern to the photocell to start temporary dimming mode in the second embodiment.

In the user-initiated dimming test mode 130, the user initiates a dimming sequence after a photocell of the photocontroller 114 receives a predefined sequence of light patterns. The user initiates the dimming sequence by pointing a light source generator 126 in the direction of a photocell 114 such that the photocell receives the predefined sequence of light patterns. During normal operation, the microcontroller 120 receives information from the photocell 114 with information regarding the ambient light condition. However, if a predefined sequence of light pattern is received by the photocell of the photocontroller 114, the microcontroller 120 will detect the condition and initiate the dimming test sequence.

The light source generator 136 can be programmed to provide a predefined light pattern that will be recognized by the photocontroller 114. The predefined light patterns will be generated such that they are not similar to typical normal outdoor lighting conditions. The light source generator 136 can be a tool with a cover 138 that blocks all other light sources so that the only light detected by the photocell 114 will be transmitted from the programmed light source generator 136. The predefined light pattern is transmitted from the programmable light source generator 136, then detected and recognized by the outdoor controller photo eye 134 and microcontroller 120.

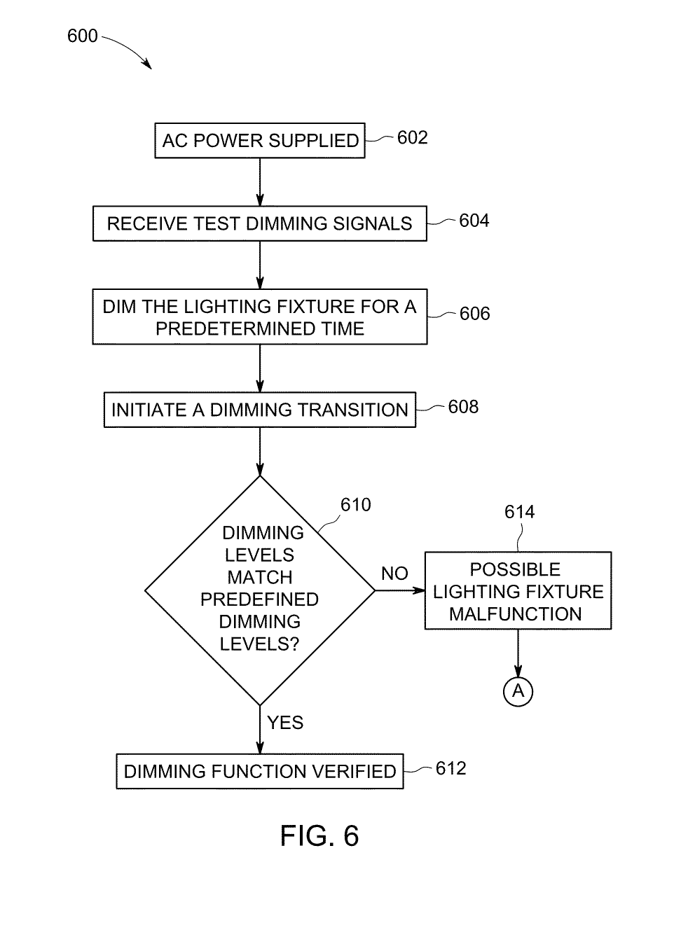

FIG. 6 is a flowchart of an exemplary method 600 of practicing a first embodiment of the present invention. In the exemplary method 700, the AC power is supplied in step 602. The microcontroller receives the test dimming signals in step 604. The test dimming signals instructs the microcontroller to enter the automatic dimming self-testing mode. In step 606, the dimming ballast dim the lighting fixture based on the predefined dimming level or levels for a predetermined time interval.

In step 608, the microcontroller initiates a dimming transition to full normal operation mode. In step 610, a check is performed to verify that the sequence of the dimming levels of the light fixture match the predefined dimming level(s). In step 610 if the sequence of the dimming level(s) of the light fixture match the predefined dimming level(s) sequence, then operation of the dimming feature is verified in step 612.

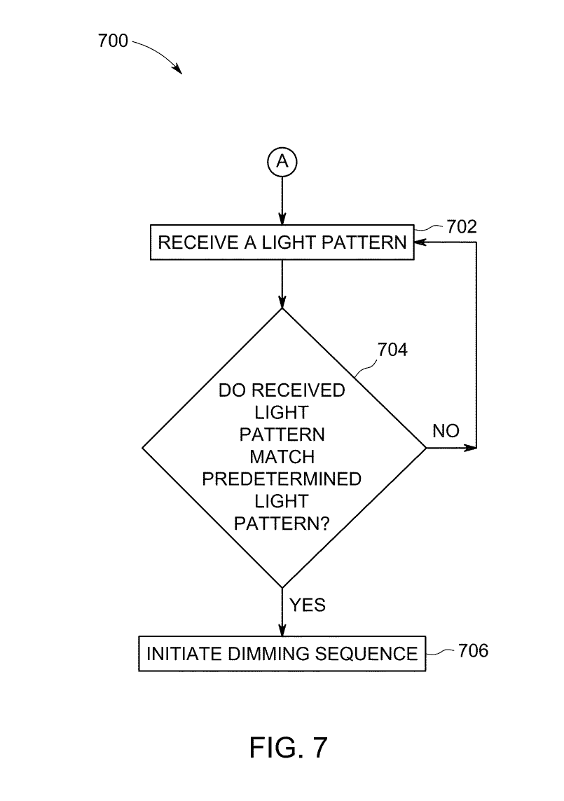

In step 610 if the sequence of the dimming level(s) of the light does not match the predefined dimming level sequence, then a light fixture malfunction alarm is trigger to alert the user of a possible malfunction in step 614. The user has the option of proceeding to FIG. 7 and selectively performing a user-initiated manual test of the dimming feature.

FIG. 7 is a flowchart of an exemplary method 700 of practicing a second embodiment of the present invention. In the exemplary method 700, the photo eye sensor receives a light pattern in step 702. In step 704, a check is performed to determine whether the light pattern matches a predetermined light pattern.

In step 702, if the light pattern received by the photo cell matches the predetermined light pattern, then the microcontroller enters the testing mode and initiates the dimming sequence in step 706. In step 702, if the light pattern received by the photo cell does not match the predetermined light pattern, the process returns to step 702.

Alternative embodiments, examples, and modifications which would still be encompassed by the disclosure may be made by those skilled in the art, particularly in light of the foregoing teachings. Further, it should be understood that the terminology used to describe the disclosure is intended to be in the nature of words of description rather than of limitation.

The term “light source” should be understood to refer to any one or more of a variety of radiation sources, including, but not limited to, LED-based sources (employing one or more LEDs as defined above), incandescent sources (e.g., filament lamps, halogen lamps), fluorescent sources, phosphorescent sources, high-intensity discharge sources (e.g., sodium vapor, mercury vapor, and metal halide lamps), lasers, other types of electroluminescent sources, pyro-luminescent sources (e.g., flames), candle-luminescent sources (e.g., gas mantles, carbon arc radiation sources), photo-luminescent sources (e.g., gaseous discharge sources), cathode luminescent sources using electronic satiation, galvano-luminescent sources, crystallo-luminescent sources, kine-luminescent sources, thermo-luminescent sources, triboluminescent sources, sonoluminescent sources, radioluminescent sources, and luminescent polymers.

The terms “lighting fixture”, “light fixture” and “lighting unit” are used interchangeably herein to refer to an apparatus including one or more light sources of same or different types. A given lighting fixture may have any one of a variety of mounting arrangements for the light source(s), enclosure/housing arrangements and shapes, and/or electrical and mechanical connection configurations. Additionally, a given lighting fixture optionally may be associated with (e.g., include, be coupled to and/or packaged together with) various other components (e.g., control circuitry) relating to the operation of the light source(s). An “LED-based lighting unit” refers to a lighting unit that includes one or more LED-based light sources as discussed above, alone or in combination with other non LED-based light sources.

The terms “processor” or “controller” are used herein interchangeably to describe various apparatus relating to the operation of one or more light sources. A processor or controller can be implemented in numerous ways, such as with dedicated hardware, using one or more microprocessors that are programmed using software (e.g., microcode) to perform the various functions discussed herein, or as a combination of dedicated hardware to perform some functions and programmed microprocessors and associated circuitry to perform other functions.

In various implementations, a processor or controller may be associated with one or more storage media (generically referred to herein as “memory,” e.g., volatile and non-volatile computer memory such as RAM, PROM, EPROM, and EEPROM, floppy disks, compact disks, optical disks, magnetic tape, etc.). In some implementations, the storage media may be encoded with one or more programs that, when executed on one or more processors and/or controllers, perform at least some of the functions discussed herein.

Various storage media may be fixed within a processor or controller or may be transportable, such that the one or more programs stored thereon can be loaded into a processor or controller so as to implement various aspects of the present invention discussed herein. The terms “program” or “computer program” are used herein in a generic sense to refer to any type of computer code (e.g., software or microcontroller code) that can be employed to program one or more processors or controllers.

Those skilled in the art will also appreciate that various adaptations and modifications of the preferred and alternative embodiments described above can be configured without departing from the scope and spirit of the disclosure. Therefore, it is to be understood that, within the scope of the appended claims, the disclosure may be practiced other than as specifically described herein.

We claim:

1. A diagnostic device for testing a lighting fixture, the lighting fixture including at least one ballast configured to receive a dimming test signal, the diagnostic device comprising:
a controller module configured to trigger a test sequence when the ballast receives the dimming test signal;
wherein an output current of the ballast is adjusted in accordance with predetermined values of the dimming test signal, the adjusted output current setting a dimming level of the lighting fixture.

2. The diagnostic device of claim 2, wherein the dimming test sequence is pre-programmable.

3. The diagnostic device of claim 2, wherein the dimming test sequence comprises a dimming transition from the dimming test mode to a normal operating mode after completion of the testing operation.

4. The diagnostic device of claim 1, wherein the dimming levels occur a predetermined period of time.

5. The diagnostic device of claim 1, wherein the controller module automatically executes the testing operation and enters the dimming testing mode when power is supplied to the lighting fixture.

6. The diagnostic device of claim 1, wherein the dimming testing component comprises a built-in self-testing architecture integral to the fixture housing.

7. The diagnostic device of claim 1, wherein the testing operation is further configured to verify operation of at least one additional component of the lighting fixture to trouble shoot operating conditions for the lighting fixture.

8. The diagnostic device of claim 1, wherein the microcontroller executes the testing operation when a predefined light sequence is detected and enters the dimming testing mode.

9. The diagnostic device of claim 8, further comprising a light source generator configured to generate the predefined light sequence.

10. The diagnostic device of claim 9, wherein the light source generator is programmable with the predefined light sequence.

11. The diagnostic device of claim 10, wherein the light source generator is a portable device.

12. The diagnostic device of claim 11, further comprising a photo eye coupled to the lighting fixture.

13. The diagnostic device of claim 12, wherein the light source generator is configured to transmit the predefined light pattern to the photo eye for detection and for instructing the microcontroller to enter the dimming testing mode.

14. A method of testing a lighting fixture, comprising:
providing at least one light source and at least one ballast or driver in a lighting fixture;
providing a controller module operatively coupled to the lighting fixture and coupled with the ballast or driver; and
providing at least one dimming test signal and at least one dimming control value from the controller module to cause the ballast or driver to provide dimmable output from the light source and instruct the controller module to enter a dimming testing mode automatically when power is supplied to the lighting fixture.

15. The method of claim 15, further comprising:
providing the at least one dimming control value based on predefined dimming levels as defined by a dimming test sequence.

16. The method of claim 15, further comprising:
providing a dimming testing component comprising a built-in self-testing architecture integral to the lighting fixture.

17. A method of testing a lighting fixture including a ballast, comprising:
providing a controller module for operative coupling to the lighting fixture; and
providing at least one dimming test signal and at least one dimming control value from the controller module to cause the ballast to provide dimmable output from the light source.

18. The method of claim 17, further comprising instructing the controller module to enter a dimming testing mode when a predefined light sequence is detected by a sensor attached to the lighting fixture.

19. The method of claim 18, further comprising:
providing the at least one dimming control value based on predefined dimming levels as defined by a dimming test sequence.

20. The method of claim 19, further comprising:
providing a light source generator that is configured to transmit the predefined light pattern towards a photo eye coupled with the lighting fixture;
sensing light patterns approximate the photo eye for detection of the predefined light pattern; and
instructing the microcontroller to enter the dimming testing mode when the photo eye detects the predefined light pattern transmitted from the light source generator; and
instructing the microcontroller to enter the dimming testing mode.
